(19) United States
(12) Patent Application Publication
(10) Pub. No.: US 2011/0174531 A1
(43) Pub. Date: Jul. 21, 2011

(54) CABLE WITH TWISTED PAIRS OF INSULATED CONDUCTORS

(76) Inventors: Michael Joseph Rubera, Colfax, NC (US); Michael Thomas Gromko, Greensboro, NC (US); Richard Walter Speer, Kernersville, NC (US)

(21) Appl. No.: 12/688,677

(22) Filed: Jan. 15, 2010

(51) Int. Cl. H05K 9/00

(52) U.S. Cl. 174/350

(57) ABSTRACT

A cable includes first and second twisted pairs of insulated conductors and a central core. The central core includes a hub and a separator extending outwardly from the hub to an end segment. The separator extends between the first and second twisted pairs to separate the first and second twisted pairs along at least a portion of a length of the cable. The cable also includes a conductive shield extending at least partially around the first and second twisted pairs and the central core. The end segment of the separator extends between the shield and the first twisted pair and is engaged with the shield. The first twisted pair is spaced apart from the shield.

### BACKGROUND OF THE INVENTION

The subject matter described and/or illustrated herein relates generally to cables, and more particularly, to cables using at least two twisted pairs of insulated conductors.

Some known data communication cables include pairs of insulated conductors that are twisted together, sometimes referred to as “twisted pairs.” When twisted pairs are closely placed, such as in a cable, electrical energy may be transferred between two or more of the twisted pairs, which is commonly referred to as “crosstalk.” As operating frequencies of data communication cables increase, improved crosstalk isolation between the twisted pairs becomes more important. For example, data communication cables must meet electrical performance characteristics required for transmission at frequencies above a predetermined threshold. The Telecommunications Industry Association (TIA) and the Electronics Industry Association (EIA) have developed standards which specify specific categories of performance for cable impedance, attenuation, skew, and particularly crosstalk isolation. One standard for crosstalk isolation is TIA/EIA-568C, wherein category cables are required to have isolation between the twisted pairs.

Various cable designs have been used to attempt to reduce crosstalk and meet industry standards. For example, some known data communication cables include twisted pairs formed with relatively tight twists. Each twisted pair has a specified distance between twists referred to as the “twist lay.” When adjacent twisted pairs have the same twist lay and/or twist direction, they tend to be more closely spaced, which may increase the amount of crosstalk. Accordingly, each twisted pair within the cable may have a unique twist lay to increase the spacing between pairs and thereby attempt to reduce crosstalk. Moreover, the twist direction of the twisted pairs may also be varied in an attempt to reduce crosstalk. However, varying twist lay and/or direction of the twisted pairs may achieve only limited crosstalk isolation.

Another attempt at solving the problem of twisted pairs lying too closely together within a cable includes a cable having four twisted pairs radially disposed about a central core. Each twisted pair nests between two separators of the central core such that each twisted pair is separated from adjacent twisted pairs by the central core. The central core preserves the geometry of the twisted pairs relative to each other, which may facilitate reducing and/or stabilizing cross talk between the twisted pairs. However, the central core may achieve only a limited reduction of crosstalk.

Accordingly, some of the problems with at least some known data communication cables include an undesirably high amount of crosstalk between twisted pairs. For example, if a cable includes more than four twisted pairs bundled within a common jacket, crosstalk levels may not comply with the transmission requirements of TIA/EIA-568C.

### BRIEF DESCRIPTION OF THE INVENTION

In one embodiment, a cable includes first and second twisted pairs of insulated conductors and a central core. The central core includes a hub and a separator extending outwardly from the hub to an end segment. The separator extends between the first and second twisted pairs to separate the first and second twisted pairs along at least a portion of a length of the cable. The cable also includes a conductive shield extending at least partially around the first and second twisted pairs and the central core. The end segment of the separator extends between the shield and the first twisted pair and is engaged with the shield. The first twisted pair is spaced apart from the shield.

In another embodiment, a cable includes an insulative jacket and sub-cables positioned within the jacket such that the jacket at least partially surrounds the sub-cables. Each of the sub-cables includes first and second twisted pairs of insulated conductors and a central core. The central core includes a hub and a separator extending outwardly from the hub to an end segment. The separator extends between the first and second twisted pairs to separate the first and second twisted pairs along at least a portion of a length of the cable. A conductive shield extends at least partially around the first and second twisted pairs and the central core. The end segment of the separator extends between the shield and the first twisted pair and is engaged with the shield. The first twisted pair is spaced apart from the shield.

In another embodiment, a cable includes first and second twisted pairs of insulated conductors and a central core. The central core includes a hub and first and second separators that extend outwardly from the hub to respective first and second end segments. The first and second separators of the central core define a channel therebetween. The first twisted pair extends within the channel. The first separator extends between the first and second twisted pairs to separate the first and second twisted pairs along at least a portion of a length of the cable. A conductive shield extends at least partially around the first and second twisted pairs and the central core. The first end segment of the first separator extends between the shield and the first twisted pair. The second end segment of the second separator extends between the shield and the first twisted pair.

### BRIEF DESCRIPTION OF THE DRAWINGS

FIG. 1 is a perspective view illustrating a cross section of a portion of an exemplary embodiment of a cable.

FIG. 2 is a perspective view of a portion of an exemplary embodiment of a central core of a sub-cable of the cable shown in FIG. 1.

FIG. 3 is a cross-sectional view of the central core shown in FIG. 2.

FIG. 4 is a cross-sectional view of an exemplary embodiment of a sub-cable of the cable shown in FIG. 1.

FIG. 5 is a cross-sectional view of the cable shown in FIG. 1.

### DETAILED DESCRIPTION OF THE INVENTION

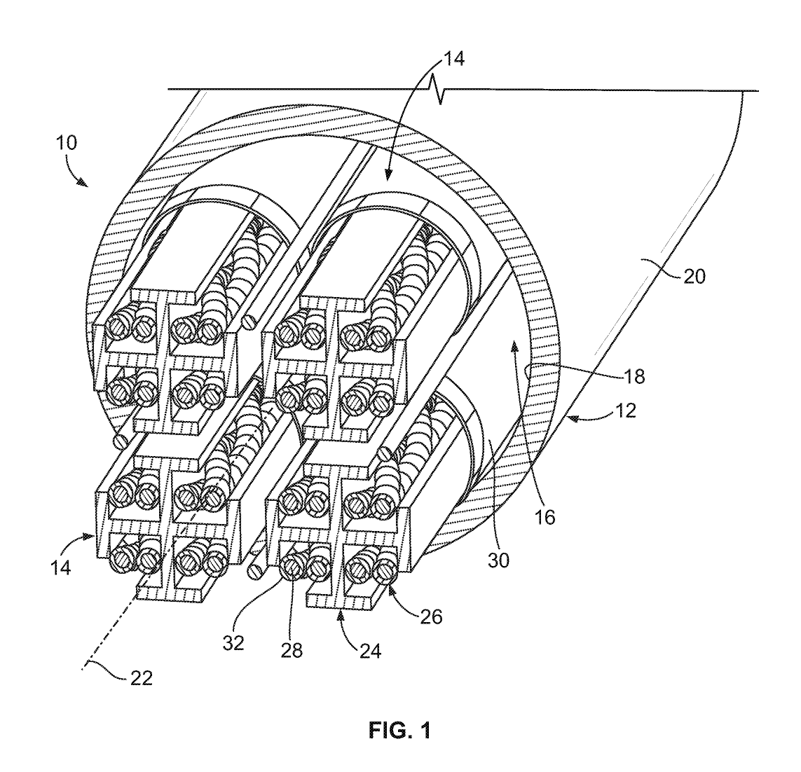

FIG. 1 is a perspective view illustrating a cross section of a portion of an exemplary embodiment of a cable 10. In the description that follows, the cable 10 will be described and/or illustrated in terms of premise cabling, such as, but not limited to, a data communication cable and/or the like. However, it is to be understood that the benefits described and/or illustrated herein are also applicable to other types of cables, including, but not limited to, wires, cords, cables, and/or the like of any type. The following description and illustrations are therefore provided for illustrative purposes only and are but one potential application of the subject matter described and/or illustrated herein.

The cable 10 includes an insulative jacket 12 and a plurality of sub-cables 14 positioned within the jacket 12. A portion of the jacket 12 has been removed from FIG. 1 to illustrate the sub-cables 14. Each sub-cable 14 may be referred to herein as a “cable”. As FIG. 1 illustrates, the jacket 12 surrounds the sub-cables 14. Specifically, the jacket 12 includes an internal passageway 16 within which the sub-cables 14 extend. The sub-cables 14 extend within the passageway 16 along the length (only a portion of which is illustrated herein) of the cable 10. The jacket 12 is fabricated from any insulative, non-conductive materials, such as, but not limited to, polyvinyl chloride (PVC) and/or the like. In the exemplary embodiment, the jacket 12 includes an approximately smooth inner surface 18 and an approximately smooth outer surface 20. In alternative embodiments, the inner surface 18 and/or the outer surface 20 may not be approximately smooth. The cable 10 and the jacket 12 extend along a central longitudinal axis 22 that extends along the length of the cable 10.

In the exemplary embodiment, each of the sub-cables 14 includes a central core 24, a plurality of twisted pairs 26 of insulated conductors 28, and a conductive shield 30. The twisted pairs 26 may each be referred to herein as a “first”, a “second”, a “third”, and/or a “fourth” twisted pair. A portion of each of the shields 30 has been removed from FIG. 1 to illustrate the central core 24 and twisted pairs 26. As will be described in more detail below, the central core 24 separates the twisted pairs 26 from one another. As described above, in the exemplary each of the conductors 28 is surrounded by an insulative layer 32. The conductors 28 may be fabricated from any conductive materials, such as, but not limited to, copper and/or the like. The insulative layers 32 are fabricated from any insulative, non-conductive materials, such as, but not limited to, polypropylene and/or the like.

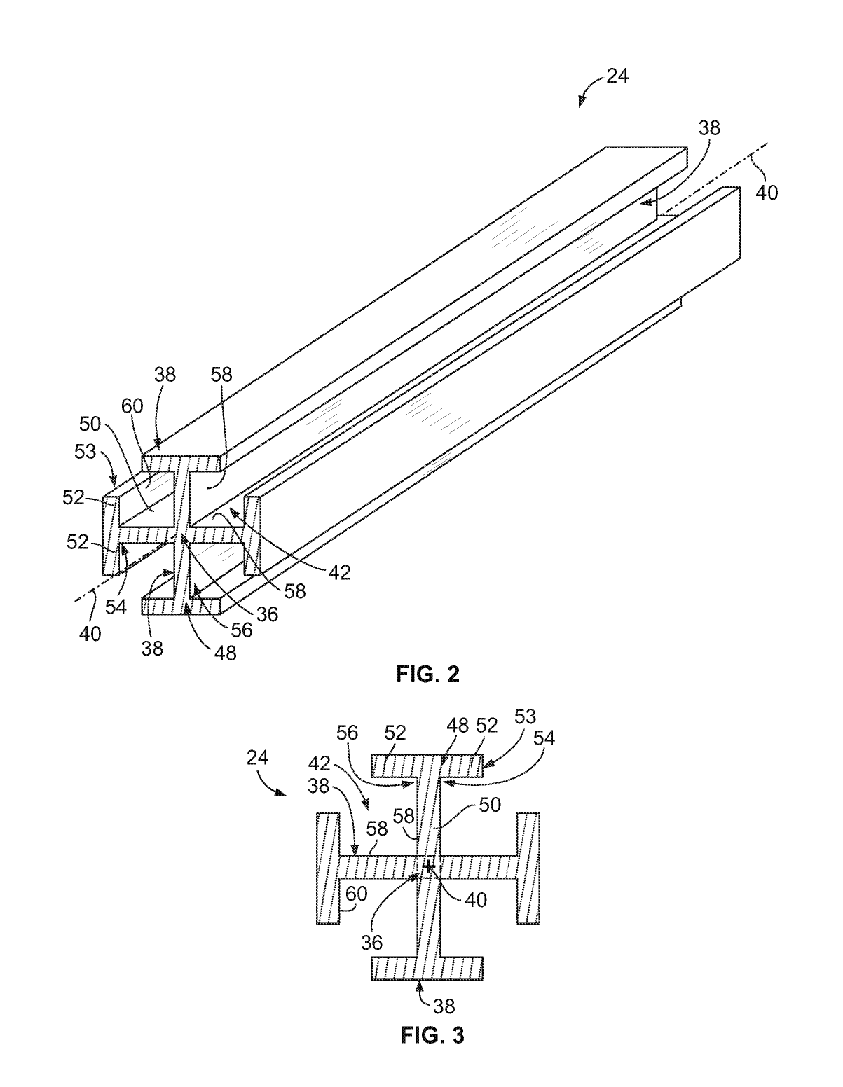

FIG. 2 is a perspective view of a portion of an exemplary embodiment of a central core 24. FIG. 3 is a cross-sectional view of the central core 24. The central core 24 includes a central hub 36 and a plurality of separators 38 that extend outwardly from the hub 36. Each of the separators 38 may be referred to herein as a “first”, a “second”, a “third”, and/or a “fourth” separator. The boundaries of the hub 36 are indicated in FIG. 3 with phantom lines for clarity. The hub 36 extends a length along a central longitudinal axis 40. The separators 38 extend radially outward from the hub 36 relative to the central longitudinal axis 40. Each adjacent pair of separators 38 defines a channel 42 therebetween. Each channel 42 is configured to receive a corresponding one of the twisted pairs 26 (FIGS. 1, 4, and 5) therein, as will be described below.

In the exemplary embodiment, the central core 24 includes four separators 38 that define four channels 42, and each channel 42 is positioned in a different quadrant of the central core 24. But, the central core 24 may include any number of the separators 38 that define any number of channels 42 for holding any number of twisted pairs 26. Moreover, the channels 42 may be arranged around the central longitudinal axis 40 in any other pattern than shown herein. The exemplary central core 24 shown herein includes a cross shape. Specifically, adjacent separators 38 of the exemplary central core 24 shown herein are angled at approximately 90° relative to each other. However, in addition or alternatively, the central core 24 may include other shapes, which may depend on the number of separators 38, the relative orientation and/or pattern of the separators 38, and/or the like.

The separators 38 extend outwardly from the hub 36. Each separator 38 includes an arm segment 50 and an end segment 48 that extends outwardly from the arm segment 50. The end segments 48 may each be referred to herein as a “first” and/or a “second” end segment. The end segment 48 of each separator 38 includes one or more finger segments 52. Each finger segment 52 may be referred to herein as a “first” and/or a “second” finger segment. The arm segments 50 extend outwardly from the hub 36. Each finger segment 52 extends outwardly from the corresponding arm segment 50 to a tip 53. Specifically, each arm segment 50 extends outwardly from the hub 36 to an end 56. The finger segments 52 extend from the arm segments 50 at bends 54 that are located at the ends 56 of the arm segments 50, such that the finger segments 52 extend outwardly from the end 56 of the corresponding arm segment 50. The finger segments 52 further define the channels 42 of the central core 24. Specifically, exterior surfaces 58 and 60 of the arm and finger segment 50 and 52, respectively, define boundaries of the channels 42. Each channel 42 is thus defined by the space extending between the exterior surfaces 58 and 60 of the corresponding separators 38.

In the exemplary embodiment, each separator 38 includes two finger segments 52 that extend outwardly from the corresponding arm segment 50 in opposite directions. Accordingly, each separator 38 includes a “T” shape, as can be seen in both FIGS. 1 and 2. Alternatively, one or more of the separators 38 includes only one finger segment 52. Moreover, in some alternative embodiments one or more of the separators 38 includes more than two finger segments 52. In the exemplary embodiment, each finger segment 52 extends outwardly from the corresponding arm segment 50 at an angle of approximately 90°. Specifically, each of the bends 54 is approximately 90°. But, each finger segment 52 may extend from the corresponding arm segment 50 at a bend 54 having any other angle than approximately 90°, such as, but not limited to, an acute or obtuse angle.

The central core 24 is optionally fabricated from one or more dielectric materials to facilitate insulating the twisted pairs from each other, such as, but not limited to, foam polypropylene and/or the like. One example of a method of forming the central core 24 with one or more dielectric materials includes extruding or molding. Optionally, the central core 24 may include conductive materials in addition or alternatively to the dielectric materials to provide shielding between the twisted pairs 26. For example, the central core 24 may be fabricated entirely from one or more conductive materials or may include a conductive layer formed on one or more dielectric materials. One example of a conductive central core 24 includes forming the central core 24 using a laminated metal tape. In some embodiments, the central core 24 is relatively flexible, while in other embodiments the central core 24 is relatively rigid.

The central core 24 shown in FIGS. 2 and 3 is an exemplary core that can be used in accordance with one embodiment of the cable and/or sub-cables described and/or illustrated herein. In addition or alternatively, other known cores could be employed with the cable and/or sub-cables described and/or illustrated herein. The central core 24 illustrated herein is a product of Cable Components Group LLC of Framingham, Mass.

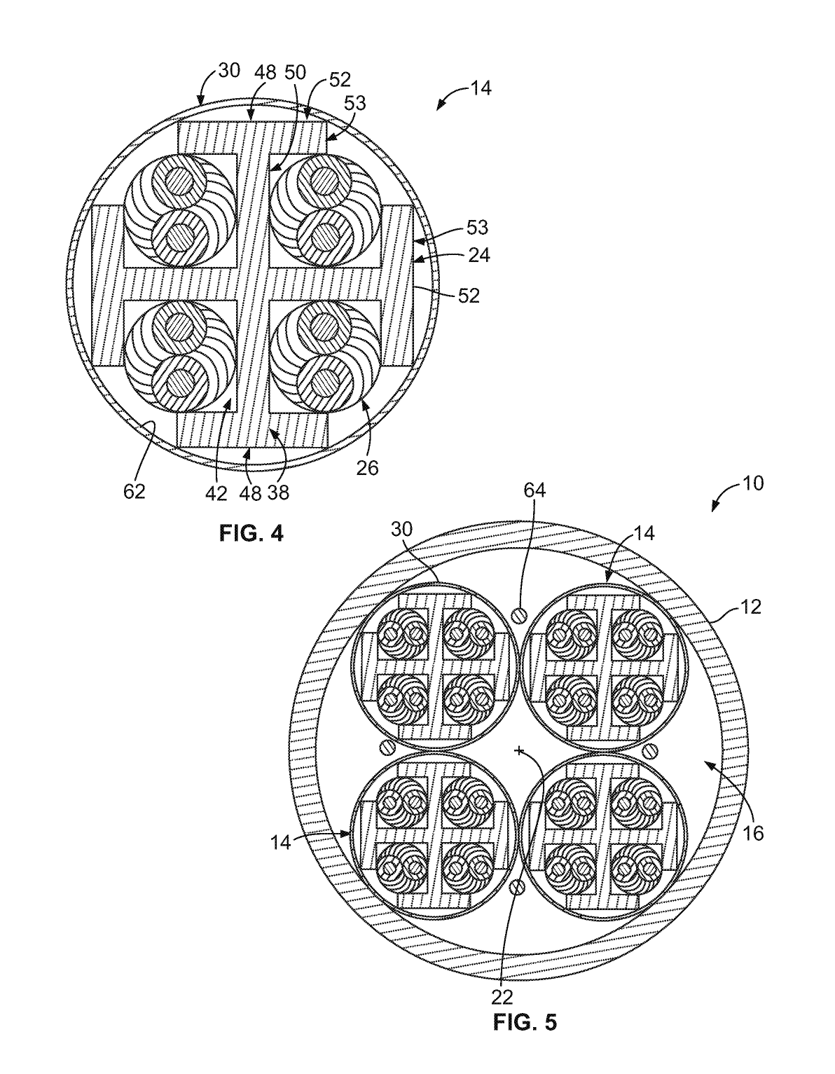

FIG. 4 is a cross sectional view of an exemplary embodiment of a sub-cable 14. In the exemplary embodiment, the sub-cable 14 includes the central core 24, four twisted pairs 26, and the shield 30. The shield 30 may be fabricated from any conductive materials, such as, but not limited to, aluminum polyimide laminated tape and/or the like. The shield 30 is optionally connected to a ground or other source of electrical energy to provide active shielding. The shield 30 extends around the central core 24 and the twisted pairs 26. Specifically, the shield 30 includes an internal passageway 62 within which the central core 24 and twisted pairs 26 extend. Each twisted pair 26 extends within a corresponding one of the channels 42 of the central core 24. Each separator 38 extends between two adjacent twisted pairs 26. Specifically, the arm segment 50 of each separator 38 extends between adjacent twisted pairs 26 to separate the adjacent twisted pairs 26 along at least a portion of the length of the sub-cable 14, and more specifically the cable 10 (FIGS. 1 and 5). As described above, the central core 24 may provide insulation and/or shielding between the twisted pairs 26. Although four are shown, each sub-cable 14 may include any number of twisted pairs 26.

The end segment 48 of each separator 38 extends between the shield 30 and one or more of the twisted pairs 26, and is optionally engaged with the shield 30 and/or the one or more twisted pairs 26. Specifically, in the exemplary embodiment, the tip 53 of each finger segment 52 extends between the shield 30 and a corresponding one of the twisted pairs 26. In the exemplary embodiment, each tip 53 is engaged with both the shield 30 and the corresponding twisted pair 26. Alternatively, one or more of the tips 53 does not engage the shield 30 and/or the corresponding twisted pair 26. Moreover, in some alternative embodiments, the central core 24 is configured to float within the passageway 62 of the shield 30 such that the tips 53 may move into and out of engagement with the shield 30. Still further, in some alternative embodiments one or more of the twisted pairs 26 is configured to float within the corresponding channel 42 such that the one or more twisted pairs 26 can move into and out of engagement with the corresponding tips 53. In addition or alternatively to the tips 53, other portions of the finger segments 52 may extend between and/or engage the shield 30 and/or the corresponding twisted pair 26.

As FIG. 4 illustrates, each twisted pair 26 is spaced apart from the shield 30. In other words, the twisted pairs 26 do the engage the shield 30. The finger segments 52 provide the spacing by extending between the twisted pairs 26 and the shield 30 as described above. The finger segments 52 also hold the twisted pairs 26 within the channels 42 and prevent the twisted pairs 26 from moving closer (than the corresponding channel 42) to the shield 30. Specifically, in the exemplary embodiment two finger segments 52 extend between each twisted pair 26 and the shield 30 to prevent the twisted pairs 26 from moving radially outward from the central longitudinal axis 40 into engagement with the shield 30. The spacing between the twisted pairs 26 and the shield 30 may facilitate reducing an amount of cross talk between twisted pairs within the sub-cable 14 and/or between the twisted pairs 26 of different sub-cables 14 within the cable 10.

The central core 24 and the twisted pairs 26 may be loaded into the passageway 62 of the shield 30 during a cabling operation. For example, the central core 24 and the twisted pairs 26 may be pulled into the passageway 62 during the cabling operation. Optionally, the central core 24 and the twisted pairs 26 are loaded into the passageway 62 simultaneously. Alternatively, the central core 24 is loaded into the passageway 62 either before or after the twisted pairs 26 are loaded into the passageway 62.

FIG. 5 is a cross-sectional view of the cable 10. The sub-cables 14 extend within the passageway 16 of the jacket 12 and are arranged radially about the central longitudinal axis 22 of the cable 10. In the exemplary embodiment, the sub-cables 14 are arranged in a pattern about the axis 22 such that the sub-cables 14 are arranged evenly about the axis 22 in different quadrants thereof In the pattern shown in herein, the sub-cables 14 are each engaged with adjacent sub-cables 14 and with the jacket 12 to facilitate holding the sub-cables 14 in position and maintaining the pattern. Alternatively, one or more of the sub-cables 14 is configured to float within the passageway 16 of the jacket 12 such that the one or more sub-cables 14 may move into and out of engagement with other sub-cables 14 and/or the jacket 12. In alternative embodiments, the sub-cables 14 may be arranged in any other pattern about the axis 22 than is shown herein. Although four sub-cables 14 are shown, the cable 10 may include any number of sub-cables 14.

Optionally, the cable 10 includes one or more drain wires 64 positioned within the passageway 16 of the jacket 12. The drain wires 64 may provide a connection between the shields 30 of the sub-cables and a source of ground or other electrical energy. In the exemplary embodiment, the cable 10 includes four drain wires 64, but the cable 10 may include any number of drain wires 64.

The sub-cables 14 may be loaded into the passageway 16 of the jacket 12 during a cabling operation. For example, the sub-cables 14 may be pulled into the passageway 16 during the cabling operation. Optionally, the sub-cables 14 are loaded into the jacket 12 simultaneously with each other and/or the drain wires 64. In some embodiments, the sub-cables 14 are loaded into the jacket 12 either before or after the drain wires 64 are loaded into the jacket 12.

The embodiments described and/or illustrated herein may provide a cable having an improved electrical performance as compared with at least some known cables. For example, the embodiments described and/or illustrated herein may provide a cable having a reduced amount of crosstalk and/or an increased amount of crosstalk isolation than at least some known cables. The embodiments described and/or illustrated herein may provide a cable having more than four twisted pairs of insulated conductors that complies with TIA/EIA-568C.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter described and/or illustrated herein without departing from its scope. Dimensions, types of materials, orientations of the various components, and the number and positions of the various components described and/or illustrated herein are intended to define parameters of certain embodiments, and are by no means limiting and are merely exemplary embodiments. Many other embodiments and modifications within the spirit and scope of the claims will be apparent to those of skill in the art upon reviewing the above description and the drawings. The scope of the subject matter described and/or illustrated herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A cable comprising:
first and second twisted pairs of insulated conductors;
a central core comprising a hub and a separator extending outwardly from the hub to an end segment, the separator extending between the first and second twisted pairs to separate the first and second twisted pairs along at least a portion of a length of the cable; and
a conductive shield extending at least partially around the first and second twisted pairs and the central core, the end segment of the separator extending between the shield and the first twisted pair and being engaged with the shield, the first twisted pair being spaced apart from the shield.

2. The cable according to claim 1, wherein the separator of the central core comprises an arm segment that extends outwardly from the hub and a finger segment that extends outwardly from the arm segment at a bend, the end segment of the separator comprising the finger segment.

3. The cable according to claim 1, wherein the separator of the central core comprises an arm segment that extends outwardly from the hub and first and second finger segments that extend outwardly from the arm segment, the end segment of the separator comprising first and second finger segments, the second finger segment extending between the shield and the second twisted pair and being engaged with the shield, the second twisted pair being spaced apart from the shield.

4. The cable according to claim 1, wherein the separator is a first separator, the central core comprising a second separator that extends outwardly from the hub of the central core, the first and second separators of the central core defining a channel therebetween, the first twisted pair extending within the channel.

5. The cable according to claim 1, wherein the separator is a first separator and the end segment is a first end segment, the central core comprising a second separator that extends outwardly from the hub of the central core, the first and second separators of the central core defining a channel therebetween, the first twisted pair extending within the channel, the second separator comprising a second end segment that extends between the shield and the first twisted pair and is engaged with the shield.

6. The cable according to claim 1, wherein the separator is a first separator, the cable further comprising a third twisted pair of insulated conductors, the central core comprising a second separator that extends outwardly from the hub of the central core, the second separator extending between the first and third twisted pairs.

7. The cable according to claim 1, wherein the central core comprises a cross shape.

8. The cable according to claim 1, wherein the separator of the central core is a first separator, the cable further comprising third and fourth twisted pairs of insulated conductors, the central core further comprising a second, a third, and a fourth separator that extend outwardly from the hub, the second separator extending between the second and third twisted pairs, the third separator extending between the third and fourth twisted pairs, and the fourth separator extending between the fourth and first twisted pairs, the shield extending at least partially around the central core and the first, second, third, and fourth twisted pairs.

9. The cable according to claim 1, wherein the end segment of the separator of the central core prevents the first twisted pair from moving closer to the shield.

10. The cable according to claim 1, wherein the end segment of the separator comprises a tip, the tip extending between and being engaged with the shield and the first twisted pair.

11. The cable according to claim 1, wherein the separator of the central core comprises an arm segment that extends outwardly from the hub and a finger segment that extends outwardly from the arm segment at an angle of approximately 90° relative to the arm segment, the end segment of the separator comprising the finger segment.

12. The cable according to claim 1, further comprising an insulative jacket at least partially surrounding the central core, the first and second twisted pairs, and the shield.

13. A cable comprising:
an insulative jacket;
sub-cables positioned within the jacket such that the jacket at least partially surrounds the sub-cables, each of the sub-cables comprising:
first and second twisted pairs of insulated conductors;
a central core comprising a hub and a separator extending outwardly from the hub to an end segment, the separator extending between the first and second twisted pairs to separate the first and second twisted pairs along at least a portion of a length of the cable; and
a conductive shield extending at least partially around the first and second twisted pairs and the central core, the end segment of the separator extending between the shield and the first twisted pair and being engaged with the shield, the first twisted pair being spaced apart from the shield.

14. The cable according to claim 13, wherein the separator of the central core comprises an arm segment that extends outwardly from the hub and a finger segment that extends outwardly from the arm segment at a bend, the end segment of the separator comprising the finger segment.

15. The cable according to claim 13, wherein the separator of the central core comprises an arm segment that extends outwardly from the hub and first and second finger segments that extend outwardly from the arm segment, the end segment of the separator comprising the first and second finger segments, the second finger segment extending between the shield and the second twisted pair and being engaged with the shield, the second twisted pair being spaced apart from the shield.

16. The cable according to claim 13, wherein the separator is a first separator, the central core comprising a second separator that extends outwardly from the hub of the central core, the first and second separators of the central core defining a channel therebetween, the first twisted pair extending within the channel.

17. The cable according to claim 13, wherein the separator is a first separator and the end segment is a first end segment, the central core comprising a second separator that extends outwardly from the hub of the central core, the first and second separators of the central core defining a channel therebetween, the first twisted pair extending within the channel, the second separator comprising a second end segment that extends between the shield and the first twisted pair and is engaged with the shield.

18. The cable according to claim 13, wherein the separator is a first separator, the cable further comprising a third twisted pair of insulated conductors, the central core comprising a second separator that extends outwardly from the hub of the central core, the second separator extending between the first and third twisted pairs.

19. The cable according to claim 13, wherein the central core comprises a cross shape.

20. A cable comprising:
first and second twisted pairs of insulated conductors;
a central core comprising a hub and first and second separators that extend outwardly from the hub to respective first and second end segments, the first and second separators of the central core defining a channel therebetween, the first twisted pair extending within the channel, the first separator extending between the first and second twisted pairs to separate the first and second twisted pairs along at least a portion of a length of the cable; and
a conductive shield extending at least partially around the first and second twisted pairs and the central core, the first end segment of the first separator extending between the shield and the first twisted pair, the second end segment of the second separator extending between the shield and the first twisted pair.
